(19) United States
(12) Patent Application Publication
(10) Pub. No.: US 2025/0283953 A1
(43) Pub. Date: Sep. 11, 2025

(54) METHOD AND APPARATUS FOR ESTIMATING SOH OF SERIES-CONNECTED CELLS, AND MACHINE-READABLE STORAGE MEDIUM

(71) Applicant: ENVISION ENERGY TECHNOLOGY PTE LTD., Singapore (SG)

(72) Inventors: WenKai GAO, Shanghai (CN); ZhongHua XU, Shanghai (CN); Yang YANG, Shanghai (CN); ZhenHua QIAN, Shanghai (CN); JingHui SHI, Shanghai (CN)

(73) Assignee: ENVISION ENERGY TECHNOLOGY PTE LTD., Singapore (SG)

(21) Appl. No.: 19/215,321

(22) Filed: May 22, 2025

Related U.S. Application Data
(63) Continuation of application No. PCT/CN2023/138535, filed on Dec. 13, 2023.

(30) Foreign Application Priority Data
Nov. 30, 2022 (CN) 202211522077.6

(51) Int. Cl. G01R 31/392; G01R 31/367; G01R 31/387; G01R 31/396; H01M 10/44

(52) U.S. Cl. CPC G01R 31/392; G01R 31/367; G01R 31/387; G01R 31/396; H01M 10/441

(57) ABSTRACT

The present disclosure relates to a method and an apparatus for estimating State of Health (SOH) of series-connected cells and a machine-readable storage medium, which are used for estimating SOH of each series-connected cell in a battery pack. The method includes: obtaining current-voltage data of each series-connected cell in the battery pack in charging and discharging processes; based on the current-voltage data of each cell, calculating a difference value between a charging terminal voltage of each cell and a standard charging terminal voltage to calculate remaining charge capacity of each cell; calculating a difference value between a discharge terminal voltage of each cell and a standard discharge terminal voltage to calculate remaining discharge capacity of each cell; and calculating actual capacity of each cell according to the remaining charge capacity and the remaining discharge capacity of each cell to evaluate the SOH of each cell.

### CROSSREFERENCE TO RELATED APPLICATION

This application is a continuation of International Application No. PCT/CN2023/138535, filed on Dec. 13, 2023, which claims priority to Chinese Patent Application No. 202211522077.6, titled “METHOD AND APPARATUS FOR ESTIMATING SOH OF SERIES-CONNECTED CELLS, AND MACHINE-READABLE STORAGE MEDIUM” and filed to the China National Intellectual Property Administration on Nov. 30, 2022, the entire contents of which are incorporated herein by reference.

### TECHNICAL FIELD

The present disclosure relates to the technical field of State of Health (SOH) of a battery estimation technology, and more particularly, to a method and an apparatus for estimating SOH of series-connected cells, and a machine-readable storage medium.

### BACKGROUND

State of Health (SOH) of a battery refers to a ratio of current capacity to nominal capacity of the battery. The SOH represents the battery's current ability to store electrical energy in percentage form. The battery continuously ages with use, leading to a gradual decrease in the SOH, and a gradual decrease in the battery's ability to store the electrical energy. According to GB/T, when the SOH of a power battery is below 80%, the battery should be replaced.

In existing SOH estimation methods, each cell requires to reach a specific equilibrium state for judgment, or requires prior acquisition of cell characterizations of different degrees of aging under different operating conditions to match, thus obtaining SOH estimation results of the battery. The above methods have shortcomings such as complex operation, limited scope of application, and low accuracy of the estimation results.

### SUMMARY

Objectives of the present disclosure are to provide a method and an apparatus for estimating SOH of series-connected cells, and a machine-readable storage medium, to overcome the shortcomings of the existing technologies. The present disclosure does not require the cells to reach a specific equilibrium state, nor does it require prior acquisition of cell characterizations of different degrees of aging under different operating conditions as a basis reference for SOH estimation.

The objectives of the present disclosure may be achieved through the following technical solutions.

A method for estimating SOH of series-connected cells is used for estimating SOH of each series-connected cell in a battery pack, where the method including following steps:
obtaining current-voltage data of each series-connected cell in the battery pack in charging and discharging processes, each cell having same charging cut-off moment and discharging cut-off moment;
according to the current-voltage data of each cell, calculating remaining charge capacity of each cell based on a difference between a charging terminal voltage of each cell and a standard charging terminal voltage; calculating remaining discharge capacity of each cell based on a difference between a discharge terminal voltage of each cell and a standard discharge terminal voltage; and
calculating actual capacity of each cell according to the remaining charge capacity and the remaining discharge capacity of each cell to evaluate the SOH of each cell.

Further, the calculating the remaining charge capacity includes:
obtaining, from the current-voltage data of a cell corresponding to the standard charging terminal voltage, a moment corresponding to a voltage point matching the charging terminal voltage of the current cell, and determining the moment as an initial moment of charging difference;
determining a moment corresponding to the charging terminal voltage of the current cell as a termination moment of charging difference; and
determining the remaining charge capacity of the current cell according to current data between the initial moment of charging difference and the termination moment of charging difference.

Further, the calculating the remaining discharge capacity includes:
obtaining, from the current-voltage data of a cell corresponding to the standard discharging terminal voltage, a moment corresponding to a voltage point matching the discharging terminal voltage of the current cell, and determining the moment as an initial moment of discharging difference;
determining a moment corresponding to the discharging terminal voltage of the current cell as a termination moment of discharging difference; and
determining the remaining discharge capacity of the current cell according to current data between the initial moment of discharging difference and the termination moment of discharging difference.

Further, the calculating the actual capacity of each cell includes:
determining standard discharge capacity according to the current-voltage data corresponding to the standard discharge terminal voltage, and determining sum of the remaining charge capacity and the remaining discharge capacity of each cell and the standard discharge capacity as the actual capacity of each cell.

Further, the standard charging terminal voltage and the standard discharging terminal voltage are selected from the current-voltage data of each cell, or are selected from nominal current-voltage data of each cell in the battery pack.

The present disclosure also provides an apparatus for estimating SOH of series-connected cells, which is used for estimating SOH of each series-connected cell in the battery pack. The apparatus includes:
a current-voltage data obtaining module configured to obtain current-voltage data of each series-connected cell in the battery pack in charging and discharging processes, each cell having same charging cut-off moment and discharging cut-off moment;
a remaining charge/discharge capacity obtaining module configured to calculate, according to the current-voltage data of each cell, remaining charge capacity of each cell based on a difference between a charging terminal voltage of each cell and a standard charging terminal voltage, and calculate remaining discharge capacity of each cell based on a difference between a discharge terminal voltage of each cell and a standard discharge terminal voltage; and
a cell SOH evaluation module configured to evaluate the SOH of each cell by calculating actual capacity of each cell according to the remaining charge capacity and the remaining discharge capacity of each cell.

Further, the remaining charge/discharge capacity obtaining module includes:
a remaining charge capacity calculation submodule configured to: obtain, from the current-voltage data of a cell corresponding to the standard charging terminal voltage, a moment corresponding to a voltage point matching the charging terminal voltage of the current cell, and determine the moment as an initial moment of charging difference;
determine a moment corresponding to the charging terminal voltage of the current cell as a termination moment of charging difference; and
determine the remaining charge capacity of the current cell according to current data between the initial moment of charging difference and the termination moment of charging difference.

Further, the remaining charge/discharge capacity obtaining module includes:
a remaining discharge capacity calculation submodule configured to: obtain, from the current-voltage data of a cell corresponding to the standard discharging terminal voltage, a moment corresponding to a voltage point matching the discharging terminal voltage of the current cell, and determine the moment as an initial moment of discharging difference;
determine a moment corresponding to the discharging terminal voltage of the current cell as a termination moment of discharging difference; and
determine the remaining discharge capacity of the current cell according to current data between the initial moment of discharging difference and the termination moment of discharging difference.

Further, the cell SOH evaluation module includes:
a submodule for calculating the actual capacity of each cell, which is configured to determine standard discharge capacity according to the current-voltage data corresponding to the standard discharge terminal voltage, and determine sum of the remaining charge capacity and the remaining discharge capacity of each cell and the standard discharge capacity as the actual capacity of each cell.

The present disclosure also provides a machine-readable storage medium, on which a computer program is stored, where the computer program is executed by a processor to perform the method described above.

Compared with the existing technologies, the present disclosure has the following advantages.
(1) The method of the present disclosure does not require the cells to reach a specific equilibrium state, nor does it require prior acquisition of cell characterizations of different degrees of aging under different operating conditions as a basis reference for SOH estimation. Instead, SOH of all the cells can be obtained based solely on the current state of the battery pack.
(2) The present disclosure has the advantage of a wide range of applications, without limiting types of the cells, which can accelerate iteration speed of new products.
(3) The method of the present disclosure does not require SOC (State of Charge) consistency between the series-connected cells.

### BRIEF DESCRIPTION OF THE DRAWINGS

FIG. 1 is a schematic diagram of solving a first actual capacity of Cell #2 in a method for estimating SOH of series-connected cells according to an embodiment of the present disclosure;

FIG. 2 is a schematic diagram of solving a second actual capacity of the Cell #2 in the method for estimating SOH of series-connected cells according to an embodiment of the present disclosure;

FIG. 3 is a schematic diagram of solving actual capacities of Cell #1 and Cell #3 in the method for estimating SOH of series-connected cells according to an embodiment of the present disclosure; and

FIG. 4 is a schematic flowchart of the method for estimating SOH of series-connected cells according to an embodiment of the present disclosure.

### DETAILED DESCRIPTION

To make the objectives, technical solutions, and advantages of the embodiments of the present disclosure clearer, the technical solutions in the embodiments of the present disclosure will be described clearly and completely below, in conjunction with the accompanying drawings in the embodiments of the present disclosure. Apparently, the described embodiments are some but not all of the embodiments of the present disclosure. Components of the embodiments of the present disclosure, as generally described and illustrated in the accompanying drawings herein, may be arranged and designed in a wide variety of different configurations.

Thus, the following detailed description of the embodiments of the present disclosure, as provided in the accompanying drawings, is not intended to limit the scope of the present disclosure as claimed, but is merely representative of selected embodiments of the present disclosure. All other embodiments obtained by a person of ordinary skill in the art based on the embodiments of the present disclosure without creative efforts shall fall within the protection scope of the present disclosure.

It is to be noted that similar reference numerals and letters indicate similar items in the following accompanying drawings. Therefore, once an item is defined in one drawing, there is no need to define and explain this item further in subsequent drawings.

### Embodiment 1

As shown in FIG. 4, the present disclosure provides a method for estimating SOH of series-connected cells, which is used for estimating SOH of each series-connected cell in a battery pack, where the method including following steps:
S1: obtaining current-voltage data of each series-connected cell in the battery pack in charging and discharging processes, each cell having same charging cut-off moment and discharging cut-off moment;
S2: according to the current-voltage data of each cell, calculating remaining charge capacity of each cell based on a difference between a charging terminal voltage of each cell and a standard charging terminal voltage; and calculating remaining discharge capacity of each cell based on a difference between a discharge terminal voltage of each cell and a standard discharge terminal voltage; and
S3: calculating actual capacity of each cell according to the remaining charge capacity and the remaining discharge capacity of each cell to evaluate the SOH of each cell.

The current-voltage data include voltage-time data and current-time data of each cell. The cells in the battery pack may be connected in parallel or in series with each other. In this solution, estimation of the actual capacity of the cells on the same series branch is jointly made.

The calculating the remaining charge capacity includes:
obtaining, from the current-voltage data of a cell corresponding to the standard charging terminal voltage, a moment corresponding to a voltage point matching the charging terminal voltage of the current cell, and determining the moment as an initial moment of charging difference;
determining a moment corresponding to the charging terminal voltage of the current cell as a termination moment of charging difference; and
determining the remaining charge capacity of the current cell according to current data between the initial moment of charging difference and the termination moment of charging difference.

The calculating the remaining discharge capacity includes:
obtaining, from the current-voltage data of a cell corresponding to the standard discharging terminal voltage, a moment corresponding to a voltage point matching the discharging terminal voltage of the current cell, and determining the moment as an initial moment of discharging difference;
determining a moment corresponding to the discharging terminal voltage of the current cell as a termination moment of discharging difference; and
determining the remaining discharge capacity of the current cell according to current data between the initial moment of discharging difference and the termination moment of discharging difference.

The calculating the actual capacity of each cell includes:
determining standard discharge capacity according to the current-voltage data corresponding to the standard discharge terminal voltage, and determining sum of the remaining charge capacity and the remaining discharge capacity of each cell and the standard discharge capacity as the actual capacity of each cell.

The standard charging terminal voltage and the standard discharging terminal voltage are selected from the current-voltage data of each cell, or are selected from nominal current-voltage data of each cell in the battery pack.

It should be noted that in this embodiment, to intuitively reflect transformation of charging data and subsequent calculation, both the charging data and discharging data are described and displayed in the form of fitting curves. In the actual calculation, the calculation may be made directly based on the current-voltage data.

Specific implementation processes are described as below.

Implementation process 1: in this implementation process, the current-voltage data of Cell #1 is selected, from the current-voltage data of each cell, as a curve with the standard charging terminal voltage and the standard discharging terminal voltage, which has the maximum charging terminal voltage and the minimum discharging terminal voltage.

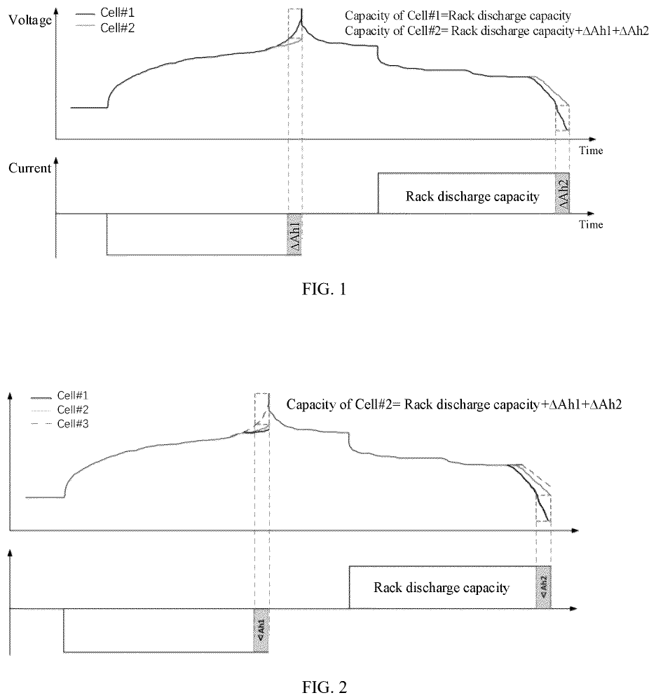

As shown in FIG. 1, to determine the actual capacity of Cell #2, based on the charging terminal voltage of Cell #2, the moment corresponding to the corresponding voltage point is sought from a charging voltage curve of Cell #1, and the remaining charge capacity ΔAh1 of Cell #2 is determined according to the corresponding current-time curve.

Based on the discharge terminal voltage of Cell #2, the moment corresponding to the corresponding voltage point is sought from a discharge voltage curve of Cell #1, and the remaining discharge capacity ΔAh2 of Cell #2 is determined according to the corresponding current-time curve.

Based on the discharge voltage curve of Cell #1, total discharge capacity (i.e. Rack discharge capacity) of Cell #1 is determined. The actual capacity of Cell #2 is equal to the Rack discharge capacity plus the remaining charge capacity ΔAh1 plus the remaining discharge capacity ΔAh2.

Implementation process 2: in this implementation process, the nominal current-voltage data of each cell in the battery pack is used as a curve with the standard charging terminal voltage and the standard discharging terminal voltage.

As shown in FIG. 2, to determine the actual capacity of Cell #2, based on the charging terminal voltage of Cell #2, the moment corresponding to the corresponding voltage point is sought from a nominal charging voltage curve, and the remaining charge capacity ΔAh1 of Cell #2 is determined according to the corresponding current-time curve.

Based on the discharge terminal voltage of Cell #2, the moment corresponding to the corresponding voltage point is sought from a nominal discharge voltage curve, and the remaining discharge capacity ΔAh2 of Cell #2 is determined according to the corresponding current-time curve.

Based on the nominal discharge voltage curve, total discharge capacity (i.e. Rack discharge capacity) of a nominal cell is determined. The actual capacity of Cell #2 is equal to the Rack discharge capacity plus the remaining charge capacity ΔAh1 plus the remaining discharge capacity ΔAh2.

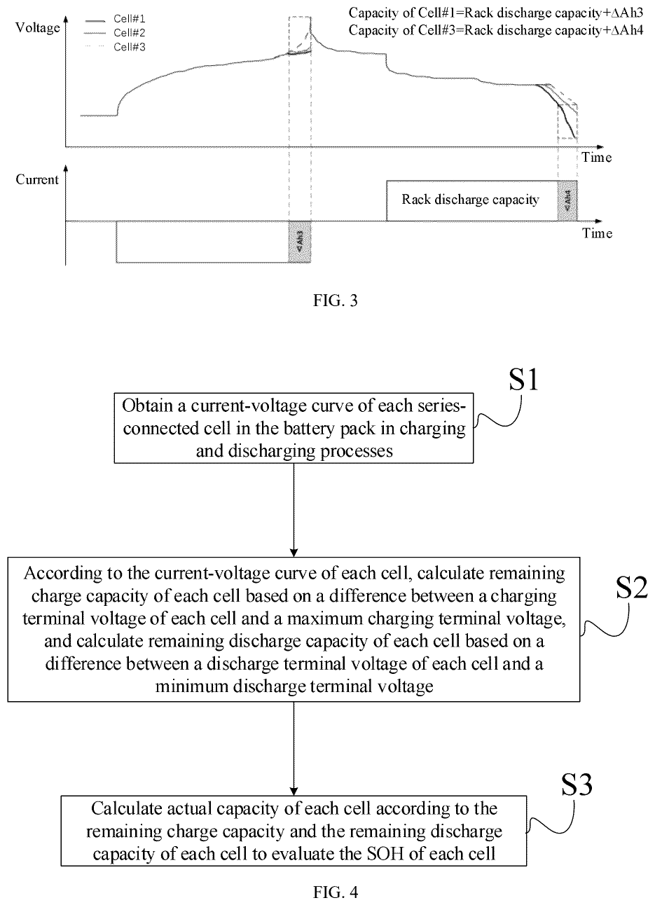

As shown in FIG. 3, to determine the actual capacity of Cell #1, based on the charging terminal voltage of Cell #1, the moment corresponding to the corresponding voltage point is sought from the nominal charging voltage curve, and the remaining charge capacity ΔAh3 of Cell #1 is determined according to the corresponding current-time curve.

The discharge terminal voltage of Cell #1 cell is equal to the terminal voltage of the nominal discharge voltage curve, so the remaining discharge capacity is equal to zero.

Therefore, the actual capacity of Cell #1 is equal to the rack discharge capacity plus the remaining charge capacity ΔAh3.

To determine the actual capacity of Cell #3, the charging terminal voltage of Cell #3 is equal to the terminal voltage of the nominal charging voltage curve, so the remaining charge capacity is equal to zero.

Based on the discharge terminal voltage of Cell #3, the moment corresponding to the corresponding voltage point is sought from the nominal discharge voltage curve, and the remaining discharge capacity ΔAh4 of Cell #3 is determined according to the corresponding current-time curve.

Therefore, the actual capacity of Cell #3 is equal to the Rack discharge capacity plus the remaining discharge capacity ΔAh4.

The method of the present disclosure does not require the cells to reach a specific equilibrium state, nor does it require prior acquisition of cell characterizations of different degrees of aging under different operating conditions. Instead, SOH of all the cells can be obtained based solely on the current state of the battery pack.

The above description is an introduction to the method embodiments. The solutions of the present disclosure are further described below with reference to an apparatus embodiment.

This embodiment also provides an apparatus for estimating SOH of series-connected cells, which is used for estimating SOH of each series-connected cell in the battery pack. The apparatus includes:
a current-voltage data obtaining module configured to obtain current-voltage data of each series-connected cell in the battery pack in charging and discharging processes, each cell having same charging cut-off moment and discharging cut-off moment;
a remaining charge/discharge capacity obtaining module configured to calculate, according to the current-voltage data of each cell, remaining charge capacity of each cell based on a difference between a charging terminal voltage of each cell and a standard charging terminal voltage, and calculate remaining discharge capacity of each cell based on a difference between a discharge terminal voltage of each cell and a standard discharge terminal voltage; and
a cell SOH evaluation module configured to evaluate the SOH of each cell by calculating actual capacity of each cell according to the remaining charge capacity and the remaining discharge capacity of each cell.

Alternatively, the remaining charge/discharge capacity obtaining module includes:
a remaining charge capacity calculation submodule configured to: obtain, from the current-voltage data of a cell corresponding to the standard charging terminal voltage, a moment corresponding to a voltage point matching the charging terminal voltage of the current cell, and determine the moment as an initial moment of charging difference;
determine a moment corresponding to the charging terminal voltage of the current cell as a termination moment of charging difference; and
determine the remaining charge capacity of the current cell according to current data between the initial moment of charging difference and the termination moment of charging difference.

The remaining charge/discharge capacity obtaining module includes:
a remaining discharge capacity calculation submodule configured to: obtain, from the current-voltage data of a cell corresponding to the standard discharging terminal voltage, a moment corresponding to a voltage point matching the discharging terminal voltage of the current cell, and determine the moment as an initial moment of discharging difference;
determine a moment corresponding to the discharging terminal voltage of the current cell as a termination moment of discharging difference; and
determine the remaining discharge capacity of the current cell according to current data between the initial moment of discharging difference and the termination moment of discharging difference.

Alternatively, the cell SOH evaluation module includes:
a submodule for calculating the actual capacity of each cell, which is configured to determine standard discharge capacity according to the current-voltage data corresponding to the standard discharge terminal voltage, and determine sum of the remaining charge capacity and the remaining discharge capacity of each cell and the standard discharge capacity as the actual capacity of each cell.

It should be noted that reference may be made to the above method embodiments for specific contents and beneficial effects of the apparatus of the present disclosure, which are not to be described in detail here.

This embodiment also provides a machine-readable storage medium, on which a computer program is stored, where the computer program is executed by a processor to perform the method described above.

In the context of the present disclosure, the machine-readable medium may be any tangible medium that may contain, or store a program for use by or in connection with an instruction execution system, apparatus, or device. The machine-readable medium may be a machine-readable signal medium or a machine-readable storage medium. The machine-readable medium may include, but is not limited to, an electronic, magnetic, optical, electromagnetic, infrared, or semiconductor system, apparatus, or device, or any suitable combination of the foregoing. More specific examples of the machine-readable storage medium may include an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

Program codes for carrying out the method of the present disclosure may be written in any combination of one or more programming languages. These program codes may be provided to a processor or controller of a general purpose computer, special purpose computer, or other programmable data processing apparatus, such that the program codes, when executed by the processor or controller, cause the functions/operations specified in the flowcharts and/or block diagrams to be implemented. The program codes may be executed entirely on a machine, partly executed on the machine, or used as a stand-alone software package to be partly executed on the machine and partly executed on a remote machine, or to be entirely executed on the remote machine or server.

The above provides a detailed description of the preferred embodiments of the present disclosure. It should be understood that those of ordinary skill in the art can make numerous modifications and changes according to the concept of the present disclosure without creative labor. Therefore, all the technical solutions that can be obtained by those skilled in the art through logical analysis, reasoning or limited experiments according to the concept of the present disclosure on the basis of the existing technologies should fall within the protection scope determined by the claims.

What is claimed is:

1. A method for estimating State of Health (SOH) of series-connected cells, wherein the method is used for estimating SOH of each series-connected cell in a battery pack, and the method comprises:
obtaining current-voltage data of each series-connected cell in the battery pack in charging and discharging processes, each cell having same charging cut-off moment and discharging cut-off moment;
according to the current-voltage data of each cell, calculating remaining charge capacity of each cell based on a difference between a charging terminal voltage of each cell and a standard charging terminal voltage; calculating remaining discharge capacity of each cell based on a difference between a discharge terminal voltage of each cell and a standard discharge terminal voltage; and
calculating actual capacity of each cell according to the remaining charge capacity and the remaining discharge capacity of each cell to evaluate the SOH of each cell.

2. The method for estimating SOH of series-connected cells according to claim 1, wherein the calculating the remaining charge capacity comprises:
obtaining, from the current-voltage data of a cell corresponding to the standard charging terminal voltage, a moment corresponding to a voltage point matching the charging terminal voltage of the current cell, and determining the moment as an initial moment of charging difference;
determining a moment corresponding to the charging terminal voltage of the current cell as a termination moment of charging difference; and
determining the remaining charge capacity of the current cell according to current data between the initial moment of charging difference and the termination moment of charging difference.

3. The method for estimating SOH of series-connected cells according to claim 1, wherein the calculating the remaining discharge capacity comprises:
obtaining, from the current-voltage data of a cell corresponding to the standard discharging terminal voltage, a moment corresponding to a voltage point matching the discharging terminal voltage of the current cell, and determining the moment as an initial moment of discharging difference;
determining a moment corresponding to the discharging terminal voltage of the current cell as a termination moment of discharging difference; and
determining the remaining discharge capacity of the current cell according to current data between the initial moment of discharging difference and the termination moment of discharging difference.

4. The method for estimating SOH of series-connected cells according to claim 1, wherein the calculating the actual capacity of each cell comprises:
determining standard discharge capacity according to the current-voltage data corresponding to the standard discharge terminal voltage, and determining sum of the remaining charge capacity and the remaining discharge capacity of each cell and the standard discharge capacity as the actual capacity of each cell.

5. The method for estimating SOH of series-connected cells according to claim 1, wherein the standard charging terminal voltage and the standard discharging terminal voltage are selected from the current-voltage data of each cell, or are selected from nominal current-voltage data of each cell in the battery pack.

6. An apparatus for estimating SOH of series-connected cells, wherein the apparatus is used for estimating SOH of each series-connected cell in a battery pack, and the apparatus comprises a processor and a memory, when executing computer programs stored in the memory, the processor is configured to:
obtain current-voltage data of each series-connected cell in the battery pack in charging and discharging processes, each cell having same charging cut-off moment and discharging cut-off moment;
calculate, according to the current-voltage data of each cell, remaining charge capacity of each cell based on a difference value between a charging terminal voltage of each cell and a standard charging terminal voltage, and calculate remaining discharge capacity of each cell based on a difference value between a discharge terminal voltage of each cell and a standard discharge terminal voltage; and
evaluate the SOH of each cell by calculating actual capacity of each cell according to the remaining charge capacity and the remaining discharge capacity of each cell.

7. The apparatus for estimating SOH of series-connected cells according to claim 6, wherein the processor is further configured to:
obtain, from the current-voltage data of a cell corresponding to the standard charging terminal voltage, a moment corresponding to a voltage point matching the charging terminal voltage of the current cell, and determine the moment as an initial moment of charging difference;
determine a moment corresponding to the charging terminal voltage of the current cell as a termination moment of charging difference; and
determine the remaining charge capacity of the current cell according to current data between the initial moment of charging difference and the termination moment of charging difference.

8. The apparatus for estimating SOH of series-connected cells according to claim 6, wherein the processor is further configured to:
obtain, from the current-voltage data of a cell corresponding to the standard discharging terminal voltage, a moment corresponding to a voltage point matching the discharging terminal voltage of the current cell, and determine the moment as an initial moment of discharging difference;
determine a moment corresponding to the discharging terminal voltage of the current cell as a termination moment of discharging difference; and
determine the remaining discharge capacity of the current cell according to current data between the initial moment of discharging difference and the termination moment of discharging difference.

9. The apparatus for estimating SOH of series-connected cells according to claim 6, wherein the processor is further configured to:
determine standard discharge capacity according to the current-voltage data corresponding to the standard discharge terminal voltage, and determine sum of the remaining charge capacity and the remaining discharge capacity of each cell and the standard discharge capacity as the actual capacity of each cell.

10. A machine-readable storage medium, wherein a computer program is stored on the machine-readable storage medium, and the computer program is executed by a processor to perform the method according to claim 1.
